(19) United States
(12) Patent Application Publication
(10) Pub. No.: US 2023/0209779 A1
(43) Pub. Date: Jun. 29, 2023

(54) SYSTEMS AND METHODS OF MAINTAINING DATA CENTER TEMPERATURE

(71) Applicant: Soluna Computing, Inc., New York, NY (US)

(72) Inventors: Nicholaus Ray Lancaster, New York, NY (US); Dipul Patel, New York, NY (US)

(73) Assignee: Soluna Computing, Inc., New York, NY (US)

(21) Appl. No.: 18/088,358

(22) Filed: Dec. 23, 2022

Related U.S. Application Data
(60) Provisional application No. 63/293,526, filed on Dec. 23, 2021.

(51) Int. Cl. H05K 7/20

(52) U.S. Cl. CPC H05K 7/20736; H05K 7/20145

(57) ABSTRACT

A data center including a housing forming an interior. The interior includes an air intake chamber, a plurality of computing devices, an exhaust chamber, and a thermal baffle. The thermal baffle is positioned between the air intake chamber and the exhaust chamber. The thermal baffle includes openings corresponding to computing devices and openings corresponding to coverings. The coverings restrict airflow from the exhaust chamber to the air intake chamber by way of the thermal baffle.

### PRIORITY

This patent application claims priority from provisional U.S. patent application number 63/293,526, filed Dec. 23, 2021, entitled, “SYSTEMS AND METHODS OF MAINTAINING DATA CENTER TEMPERATURE,” and naming Nicholaus Ray Lancaster and Dipul Patel as inventors, the disclosure of which is incorporated herein, in its entirety, by reference.

### FIELD

Illustrative embodiments generally relate to data centers and, more particularly, various embodiments relate to managing thermal profiles of data centers.

### BACKGROUND

Data centers are buildings or groups of buildings used by enterprises to house computer systems and associated components that contain critical applications and data. A data center typically supports a variety of business applications and activities, including email and file sharing, artificial intelligence, machine learning, and communications services. These activities are enabled through the infrastructure for network connectivity, central processing, and data storage within the data center.

Embodied within the data center building(s) are computers and servers, telecommunication and storage systems, and security systems. Data centers require large amounts of electricity to operate. To keep the facility running at optimal capacity and reliability, the building(s) is also typically equipped with environmental controls, such as ventilation and cooling systems, as well as redundant-capacity components. Increased temperatures in data centers can cause equipment malfunction and reduce the overall life of the equipment.

### SUMMARY OF VARIOUS EMBODIMENTS

In accordance with one embodiment of the invention, a data center includes a housing forming an interior. The interior includes an air intake chamber, a plurality of computing devices, an exhaust chamber, and a thermal baffle. The thermal baffle is positioned between the air intake chamber and the exhaust chamber. The thermal baffle includes openings corresponding to computing devices and openings corresponding to coverings. The coverings restrict airflow from the exhaust chamber to the air intake chamber by way of the thermal baffle.

In some embodiments, the data center may have an exhaust fan to draw air from the exhaust chamber into an environment or an air intake fan to move air from the environment to the air intake chamber. In some embodiments, the plurality of computing devices includes a plurality of cooling fans.

In some embodiments, the data center has a control system to operate at least one of the air intake fan, the exhaust fan, and the plurality of cooling fans to generate an air pressure differential between the exhaust chamber and the air intake chamber. The plurality of coverings may seal the second plurality of openings in response to an air pressure differential of the data center.

In some embodiments, the plurality of computing devices is located in the air intake chamber, the plurality of coverings is located on an exhaust chamber side of the thermal baffle, and a second plurality of coverings is located on the exhaust chamber side of the thermal baffle and correspond to the first plurality of openings. The plurality of computing devices may be at least partially located in the exhaust chamber.

In accordance with another embodiment of the invention, a method for air cooling a data center separates an air intake chamber and an exhaust chamber using a thermal baffle having a plurality of openings. The method then aligns a plurality of computing devices with a portion of the plurality of openings. The method then moves air into the exhaust chamber. The method then restricts, using a plurality of coverings corresponding to a remaining portion of the plurality of openings, air backflow from the exhaust chamber to the air intake chamber through the thermal baffle.

Moving air into the exhaust chamber may include operating a plurality of cooling fans of the plurality of computing devices.

Restricting the air backflow may include sealing the plurality of coverings in response to operating the plurality of cooling fans. Restricting the air backflow may also include pressurizing the exhaust chamber.

Moving air into the exhaust chamber may include operating an exhaust fan positioned between the exhaust chamber and an environment, and restricting the air backflow may include sealing the plurality of coverings in response to a controlled air flow volume differential between the plurality of cooling fans and the exhaust fan.

In some embodiments, the method may position the plurality of computing devices in the air intake chamber.

In some embodiments, the method may remove one of the plurality of computing devices from a first opening of the plurality of openings and restrict, using one of the plurality of coverings, air backflow from the exhaust chamber to the air intake chamber through the first opening.

In accordance with another embodiment of the invention, a data center includes a plurality of computing devices, at least one fan, and a thermal baffle. The at least one fan moves air through the data center. The thermal baffle includes openings to align with the plurality of computing devices, and a covering to seal and unseal one of the plurality of openings. The seal also partially obstructs airflow through the one of the plurality of openings in one direction in response to air moving through the data center.

The at least one fan may be a cooling fan of the plurality of computing devices, an air intake fan, or an exhaust fan. The at least one fan may pressurize one side of the thermal baffle.

The covering may seal in response to pressurizing the one side of the thermal baffle.

In some embodiments, the data center has an air intake chamber and an exhaust chamber. The air intake chamber and the exhaust chamber may be separated by the thermal baffle. The data center may also have a housing forming an interior including the air intake chamber, the exhaust chamber, and the thermal baffle. The covering partially obstructs airflow through the thermal baffle from the exhaust chamber to the air intake chamber.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The patent or application file contains at least one drawing executed in color. Copies of this patent or patent application publication with color drawing(s) will be provided by the Office upon request and payment of the necessary fee.

Those skilled in the art should more fully appreciate advantages of various embodiments of the invention from the following “Description of Illustrative Embodiments,” discussed with reference to the drawings summarized immediately below.

FIG. 1 schematically shows a data center arrangement in accordance with various embodiments.

FIGS. 2-3 schematically show data centers in accordance with various embodiments.

FIGS. 4-5 schematically show thermal baffle coverings in accordance with various embodiments.

FIG. 6 schematically shows a computing device in accordance with various embodiments.

FIGS. 7-8 graphically show temperature and air velocity profiles of the data center in accordance with various embodiments.

FIG. 9 graphically shows exhausted air dissipation of a data center arrangement in accordance with various embodiments.

FIG. 10 shows a process for cooling a data center in accordance with various embodiments.

### DESCRIPTION OF ILLUSTRATIVE EMBODIMENTS

In illustrative embodiments, a data center has an air intake chamber, an exhaust chamber, and a thermal baffle directing airflow through the data center. To cool the computing devices and maintain a non-harmful temperature inside the data center, air is moved through the air intake chamber, then through the computing devices, and then through the exhaust chamber. The thermal baffle maintains the unidirectional air flow, further protecting the computing modules and technicians. As air moves from the air intake chamber to the exhaust chamber, the air passes through openings in the thermal baffle directing the air through computing devices. The thermal baffle may have more openings than the data center has computing devices. To prevent the air heated by the computing devices from circulating in the data center, coverings may seal the unused openings. In other embodiments, computing devices may have coverings that, when the computing devices are removed, cover the otherwise open space in the baffle. Details of illustrative embodiments are discussed below.

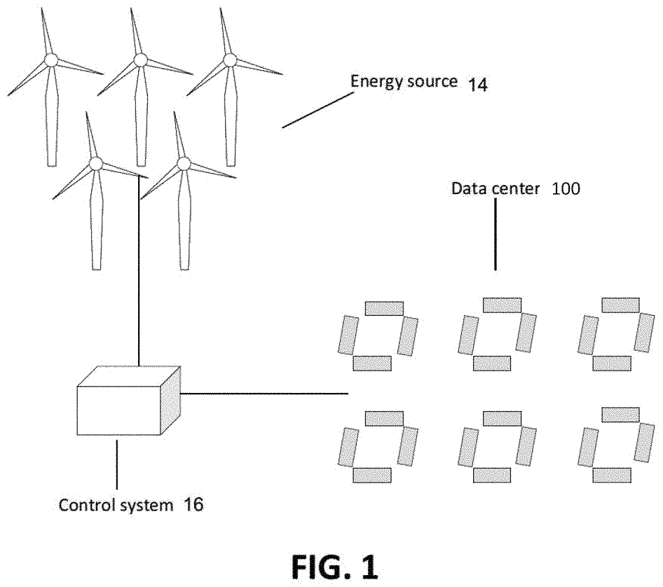

FIG. 1 schematically shows an arrangement of data centers 100 configured to protect computer systems from a surrounding environment in accordance with various embodiments. An energy source 14 provides power to the data centers 100. In the illustrated embodiment, the energy source 14 is a wind energy farm. In other embodiments, the energy source may be another type of renewable energy source, a non-renewable energy source, an electric grid, an energy storage device, or a combination thereof, among other things.

Connections to an electric grid may be so-called “behind-the-meter” and/or “in-front-of-the-meter.” For example, such embodiments may use electricity from the conventional electric grid at times when utility electricity costs are lower, and then use renewable power when utility electricity costs are higher. In fact, even when using the conventional grid, the renewable energy source can generate and store energy in batteries or other means for future use (e.g., when the conventional electric grid costs are high), and/or sell excess renewably produced energy back to the conventional electric grid.

The data centers 100 have a control system 16 that, among other things, stores and manages the supply of electricity generated by the energy source 14. To that end, the control system 16 supplies electricity to the above noted data centers 100 via the noted energy source(s) 14. This control system 16 may be pre-programmed to automatically select when and which energy source to use (e.g., the grid or local renewable and/or a microgrid), amounts, etc. In addition, the control system 16 may have user interfaces to facilitate manual grid control, as well as control of various control functions for managing the data centers 100 and their systems.

In various embodiments, some or all of the data centers 100 are permanently built in the environment. For example, each data center 100 may be constructed with conventional building techniques and products that make the data center 100 substantially permanent (i.e., analogous to a conventional house or office building). For example, each data center 100 may be placed on a cement pad or foundation and secured in a substantially permanent manner to the ground. Indeed, there are cumbersome and extraordinary ways to move a permanent structure, such as a house, and the module design in such embodiments may be subject to moving such ways.

In other embodiments, however, the data centers 100 are secured to the environment in a manner where they may be more readily moved, analogous to a trailer or some mobile homes. Specifically, they may be sized and placed in the environment with equipment that makes module movement more available. For example, a given data center 100 may be placed on a prepared portion of the ground at the desired location in the environment and nominally secured with stakes, fasteners, or other techniques. To move a data center 100 (e.g., to fine tune their positions for optimal position relative to the prevailing wind), workers or others may simply remove any ground (removably) coupling equipment and move the data center 100 to the desired new location.

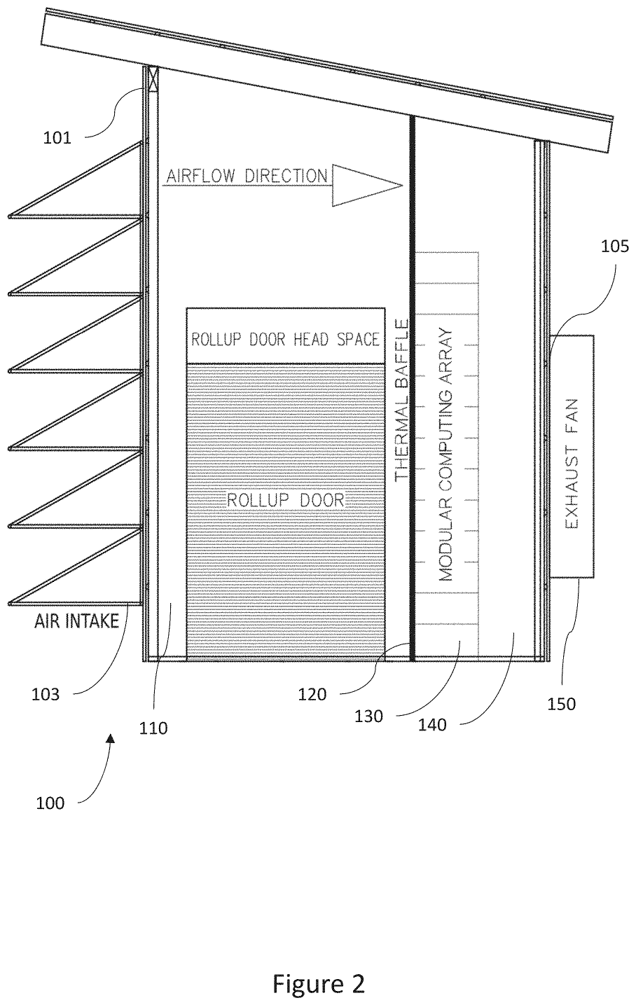

FIG. 2 schematically show the data center 100 in accordance with various embodiments. Air moves through marked sections of the data center 100, as indicated by the arrow identified as “AIRFLOW DIRECTION.”

To protect interior components from the environment, the data center 100 has a housing 101 forming a thermally controlled interior. The housing 101 may be implemented as a rectangular metal container, but may have other form factors and/or be formed from wood, plastic, concrete and other structural materials, or a combination of materials. The housing 101 may have a sloped roof specially configured to manage airflow external, but proximate to, the data center 100. The housing 101 thus is a substantially enclosed structure that shelters its interior components from the environment. In various embodiments, such as some of those noted above, the housing 101 is structured so that the data center 100 is portable and thus, it can be transported to different locations. For example, the housing 101 may be comprised of a shipping container, among other things.

The data center 100 has a modular computing array 130 including computing devices 131. Each computing device 131 may have a cooling system, such as a fan, to move air through the computing device 131 and extract heat from the computing device 131, thereby cooling the computing device 131. It should be appreciated that a fan may be any device to move air, such as a blower or a turbine, among other things.

The data center 100 has air intake ports 103 that allow air from the surrounding environment to enter the data center 100. In other embodiments, the data center 100 may have more or fewer air intake ports 103, or air intake ports 103 with a different arrangement or position. The air intake ports 103 may have filters to reduce exterior contaminants, such as dust, among other things. In some embodiments, the velocity of the air entering the data center 100 through the air intake ports 103 is low enough that any remaining dust particles settle onto the floor of the air intake chamber 110 before reaching the modular computing array 130. In other embodiments, one or more air intake fans draw air into the data center 100 through the air intake ports 103.

The data center 100 includes an air intake chamber 110 to receive the air from the air intake ports 103. The air intake chamber 110 is formed by the housing 101 and a thermal baffle 120 configured to insulate the air intake chamber 110 from the heat produced by the modular computing array 130. In some embodiments, the air intake chamber 110 is large enough for users to enter the air intake chamber 110 to maintain the modular computing array 130 and other data center 100 components.

The data center 100 has an exhaust chamber 140 to receive the heated air from the modular computing array 130. The exhaust chamber 140 is formed by the housing 101 and the thermal baffle 120.

The data center 100 includes an exhaust port 105 in the housing 101 to allow heated air to be exhausted from the data center. The data center 100 may include one or more exhaust ports 105. In the illustrated embodiment, the exhaust port 105 has an exhaust fan 150 to draw heated air from the exhaust chamber 140 into the surrounding environment of the data center 100. In some embodiments, the data center 100 may have more than one exhaust fan 150. In an alternative embodiment, the thermal baffle 120 may be located directly on the exterior wall of the data center 100, thus negating the need for thermal exhaust fans.

The thermal baffle 120 separates the air intake chamber 110 and the exhaust chamber 140. For example, the thermal baffle 120 may extend from the floor to the ceiling and across the entire structure from wall to wall, or it may have dimensions that partially cover the height and width of the data center 100 interior structure.

The thermal baffle 120 may be comprised of any thermally insulative material, or even materials that may be thermal conductors. For example, the thermal baffle 120 may be comprised of insulation foam board, plywood, fiberglass, suitable polymers, glass, metal, concrete, brick, or any suitable building material.

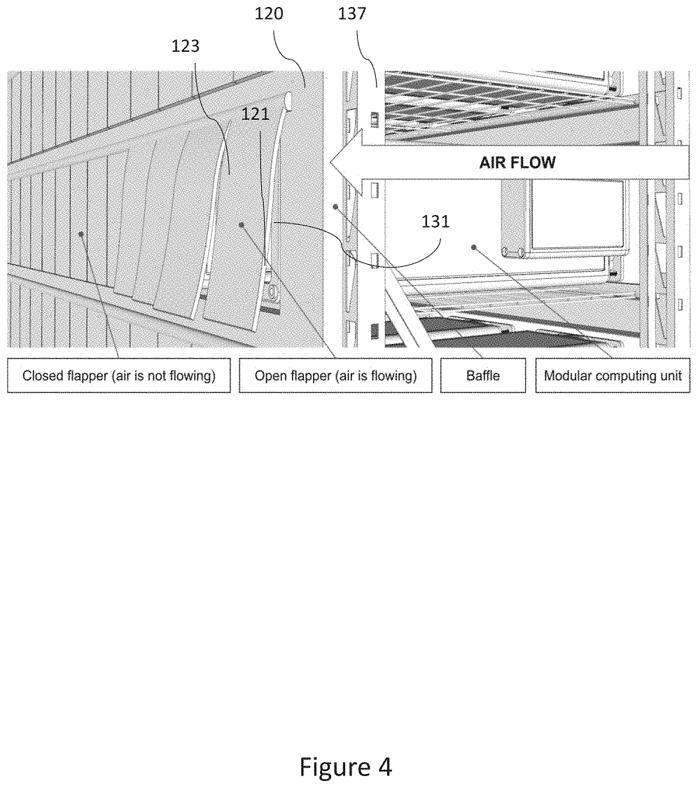

Openings 121 in the thermal baffle 120 (as in FIG. 4) direct air through the computing devices 131 of the modular computing array 130. When the thermal baffle 120 is in front of the computing array (as in FIG. 2), each opening 121 of the thermal baffle 120 may be comprised of a hole (e.g., a cutout or specially formed opening) in the thermal baffle 120 that accommodates the dimensions of one or more computing devices 131 such that an airtight (or nearly airtight) seal facilitates thermal insulation and one-way airflow.

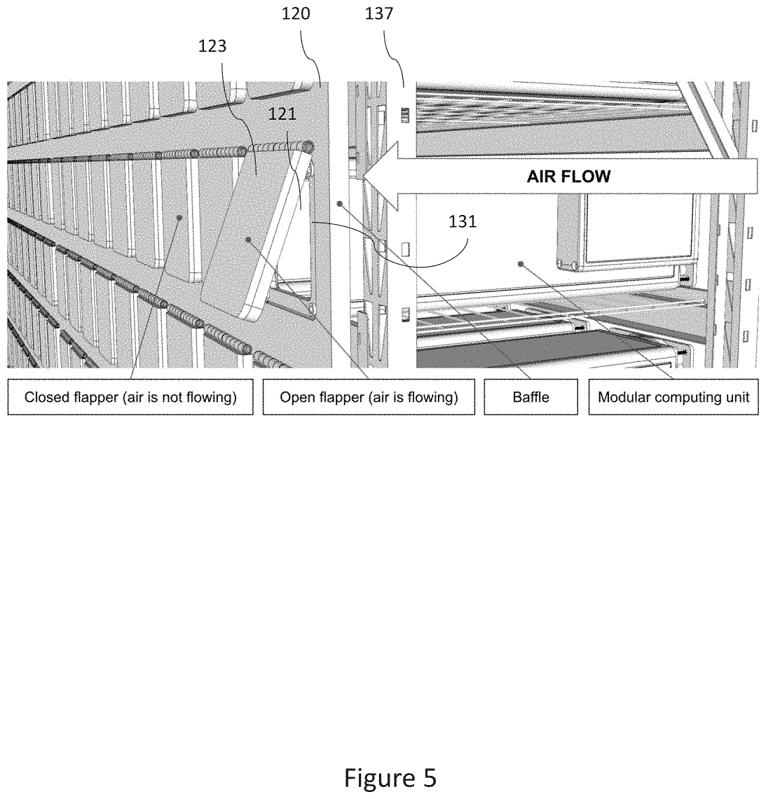

When the thermal baffle 120 is in the back of the modular computing array 130 (as in FIGS. 4-5), the back of each computing device 131 may be in contact with the thermal baffle 120 such that an airtight (or nearly airtight) seal facilitates thermal insulation and one-way airflow.

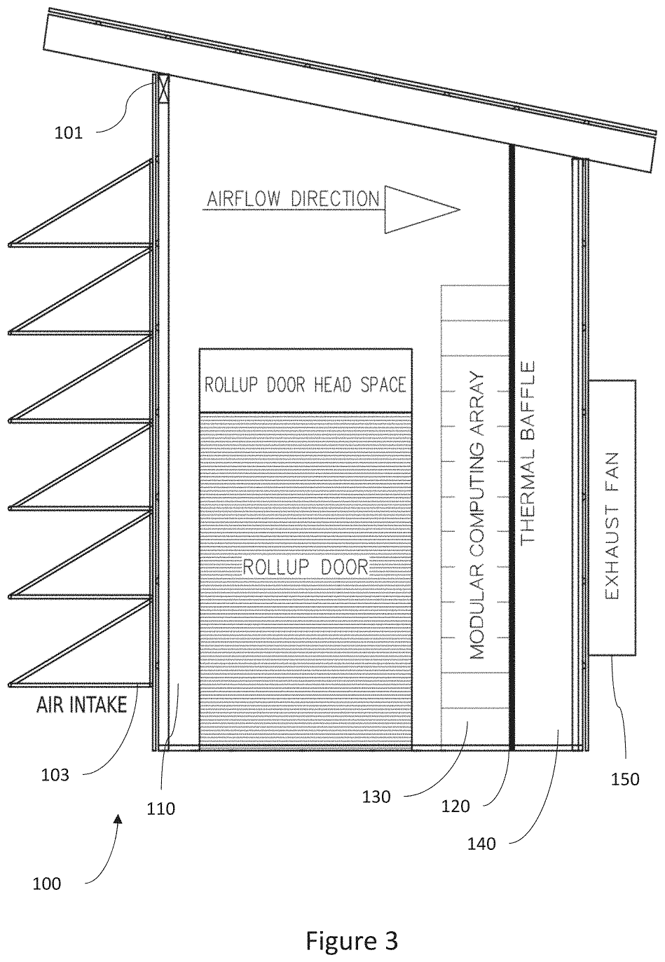

For some embodiments (as in FIGS. 2 and 3), some openings of the thermal baffle 120 may not align with one of the computing devices 131 because the number of openings 121 exceed the number of computing devices 131. Where the thermal baffle 120 has unused openings 121, the thermal baffle 120 may have coverings 123 to restrict airflow from the exhaust chamber 140 to the air intake chamber 110 by way of the thermal baffle 120. Each opening 121 of the thermal baffle 120 may have a covering 123, or only the unused openings 121 may have coverings 123, among other things.

The coverings 123 may restrict airflow through the unused openings 121 by closing due to an air pressure differential between the air intake chamber 110 and the exhaust chamber 140. By pressurizing one of the chambers of the data center 100, coverings 123 associated with unused openings 121 may be sealed. For example, for coverings 123 positioned on the exhaust chamber side of the thermal baffle 120, unused openings 121 will be sealed by the coverings 123 when the air pressure of the exhaust chamber 140 is greater than the air pressure of the air intake chamber 110. The difference in air pressure may be caused by the collective cubic feet per minute airflow of the cooling fans of the modular computing array 130 being greater than the cubic feet per minute of air moving through the exhaust port 105 and/or exhaust fans 150. In some embodiments, the control system 16 may control the opening and closing of the coverings 123 by controlling the cubic feet per minute airflow of the cooling fans of the modular computing array 130 and the exhaust fan 150.

In another example, for coverings 123 positioned on the air intake chamber side of the thermal baffle 120, unused openings 121 will be sealed by coverings 123 when the air pressure of the air intake chamber 110 is greater than the air pressure of the exhaust chamber 140. The difference in air pressure may be caused by the collective cubic feet per minute airflow of an air intake fan being greater than the cubic feet per minute of cooling fans of the modular computing array 130. In some embodiments, the control system 16 may control the opening and closing of the coverings 123 by controlling the cubic feet per minute airflow of the cooling fans of the modular computing array 130 and the air intake fan.

The coverings 123 may swing in the direction of air flow only, or in both directions. To that end, the thermal baffle 120 may have a stop that prevents the coverings 123 from swinging beyond a certain rotational amount (e.g., not beyond perpendicular to the ground in the direction opposite air flow). Moreover, in some embodiments, one or more of the coverings 123 may have a force element, such as a spring, to normally urge it closed. In related embodiments, one or more of the coverings 123 may be formed with a natural bias toward closing the opening in the thermal baffle 120.

By restricting airflow through the unused openings, the air passing through the data center is concentrated to pass through the modular computing array 130 to more efficiently cool the modular computing array 130. Restricting airflow through the unused openings also prevents heated air in the exhaust chamber 140 from recirculating into the air intake chamber 110, thereby heating the air intended to cool the modular computing array 130.

As shown in FIG. 3, the thermal baffle 120 may be positioned behind the modular computing array 130. In this arrangement, the modular computing array 130 is located in the air intake chamber 110 rather than the exhaust chamber 140.

FIGS. 4-5 schematically show the thermal baffles 120 on the backside of the modular computing array 130 such that the modular computing array 130 is positioned in the air intake chamber 110. In the illustrated embodiments, the modular computing array 130 has one computing device 131.

FIG. 4 shows the thermal baffle 120, its openings 121 and corresponding coverings 123. One of the openings 121 is aligned with the computing device 131, and the remaining openings 121 are unused by the modular computing array 130. The computing device 131 is mounted to a shelving system 137 configured to hold the computing devices 131 in place such that the thermal baffle 120 may be adjoined to the computing devices 131 or the shelving system 137. The shelving system 137 may be comprised of one or more of STYROFOAM, wood, plastic, or metal, among other things.

The coverings 123 may be made from a flexible material, such as such as natural rubber, synthetic rubber, silicone, any suitable polymer, textiles, or any suitable flexible building material. The coverings 123 may be attached to the thermal baffle 120 or attached to the housings 131 of the computing device 131. Where attached to the thermal baffle 120, the coverings 123 may either be aligned to specific computing device housings or aligned to cover the thermal baffle 120 (i.e. either in patches, in rows, in columns, for a portion of the surface, or for the whole surface).

The covering 123 aligned with the computing device 131 opens as air flows through the computing device 131, propelled by the cooling fan 135 of the computing device 131, towards the covering 123. For remaining coverings 123 with no corresponding computing device 131, the coverings 123 remain closed in order to prevent the backflow of air from the exhaust chamber 140 to the air intake chamber 110 through the unused openings 121 of the thermal baffle. The unused coverings 123 also remain closed to direct the air through the computing devices 131 in order to maximize the cooling efficiency of the air flow through the data center.

In FIG. 5, the thermal baffle 120 has openings 121 and corresponding coverings 123. One of the openings 121 is aligned with the computing device 131, and the remaining openings 121 are unused by the modular computing array 130.

The coverings 123 may be made from a rigid material, such as such as metal, wood, insulation foam, cardboard, polystyrene, polycarbonate, any suitable rigid (e.g., cross-linked) polymer, or any suitable rigid building material, among other things. The coverings 123 may be attached to the thermal baffle 120 or attached to the housings 133. Where attached to the thermal baffle 120, the coverings 123 may either be aligned to specific computing device housings or aligned to cover the thermal baffle 120 (i.e. either in patches, in rows, in columns, for a portion of the surface, or for the whole surface).

The covering 123 of FIG. 5 is a hinged flap configured to open as air flows through the computing device 131, propelled by the cooling fan of the computing device 131, towards the covering 123. In some embodiments, as suggested above, the hinged flap may be biased towards the closed position by a spring, among other things. The bias may be tuned to open certain amounts based on anticipated air flows and pressures across the system. Instead of a horizontal hinge, the covering may have a vertical hinge on the side of the covering 123 or down the middle of the covering 123. In some embodiments, the hinged flap may be mechanically or electrically operated to open or close. For example, an electric motor may open or close the hinged flaps. The electric motor may be controlled by a user input switch, or by the control system 16, among other things. In other embodiments, gravity may move the hinged flap to the closed position.

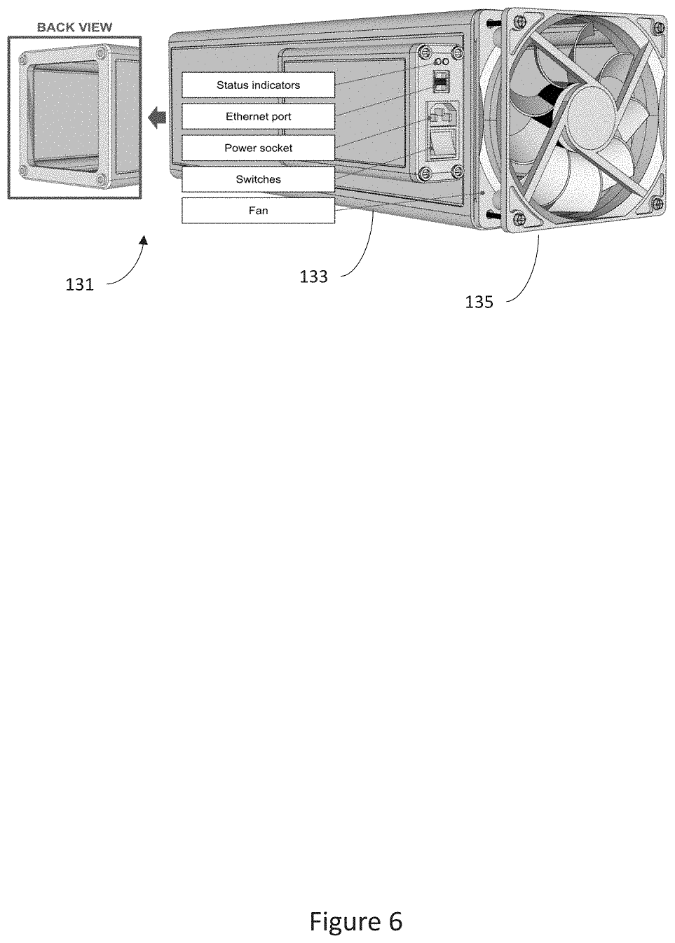

FIG. 6 schematically shows the computing device 131 of the modular computing array 130 in accordance with various embodiments. The computing device 131 has a housing 133 configured to allow air to flow through the housing 133. The housing 133 of various embodiments may be implemented as a rectangular metal container, but may have other form factors and/or be formed from wood, plastic, concrete, other structural materials, or a combination of materials.

To provide its core function, the housing 133 contains at least one processing device. Among other things, the processing device may include a computer, a server, or networking equipment (e.g., switches and routers). Those skilled in the art should understand that these components are illustrative and there is a variety of hardware, software, and combinations of hardware and software that can establish the functional components of a processing device and related accessories. The processing devices contained within the modular computing array 130 perform any of a variety of common functions to support applications, such as blockchain computing, web services, video or other multi-media transmission, storage, and data management.

As known by those in the art, the processing devices, as well as other components, within the modular computing array 130 generate substantial amounts of heat during use. Environmental factors, such as high outdoor temperatures or sun exposure also may increase the temperature within the data center 100 and the modular computing array 130. Accordingly, each computing device 131 has a (local) cooling system 135 that directs air flow from an air intake on one side of the computing device housing 133 to an air exhaust on the opposite side. In the illustrated embodiment, the cooling system 135 is a fan mounted on one side of the housing 133. The fan may be mounted on the air intake or the air exhaust of the housing 133.

The computing devices 131 may be modular units standardized to fit into arrays of shelving or other mounting architecture. The computing devices 131 may align homogeneously (either in the back or front) along the thermal baffle 120 to ensure one-way air flow through the data center 100.

The length of individual computing devices 131 may vary to accommodate different types of internal components. In some embodiments, there may be different standardized dimensions for the housings 133 such that a broader variety of equipment configurations may be employed within the same data center 100.

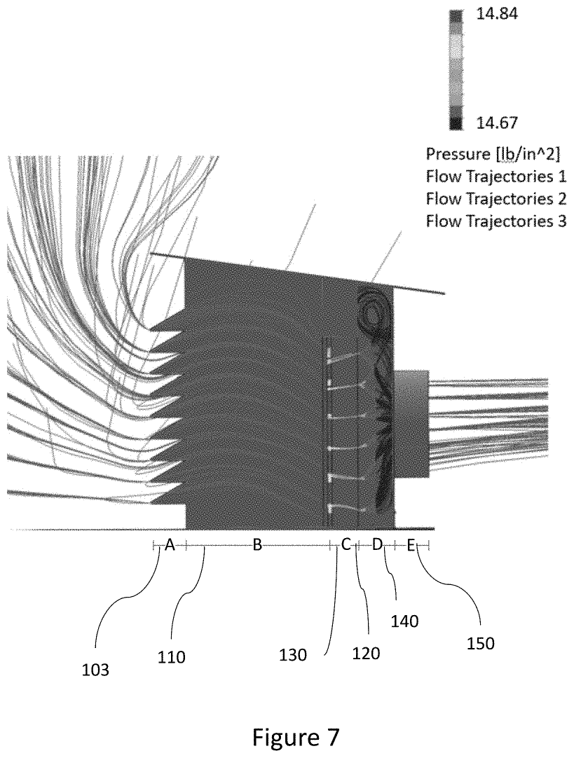

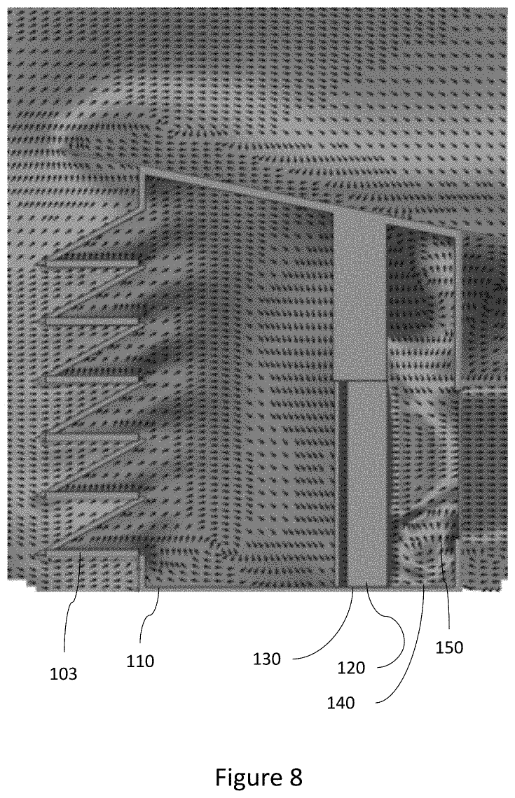

FIGS. 7 and 8 graphically show temperature and air velocity profiles of the data center 100 in accordance with various embodiments. The colors represent the average temperature of the air flowing at any given location (i.e. blue is colder and red is hotter). Air from the environment surrounding the data center 100 enters the air intake chamber 110 through the air intake ports 103. In the illustrated embodiment, the air enters the data center 100 without the use of an intake fan to prevent clogging air filters in the air intake ports 103. The air is then moved through the modular computing array 130 including each computing device 131. The air moving through the modular computing array 130 extracts heat from the computing devices 131 and carries the heat through the thermal baffle 120 to the exhaust chamber 140. The thermal baffle 120 isolates the heated air from the air intake chamber, also known as the workspace, and the modular computing array 130. The exhaust fan 150 draws the heated air from the exhaust chamber 140 into the surrounding environment. It is important to note the heated air does not backflow into the air intake chamber due to the features of the thermal baffle 120. It is also important to note that the data center 100 roof is angled to facilitate one-way airflow through the data center 100 and features extended roof edges that may prevent hot air from the exhaust fan 150 from recirculating into the air intake ports 103.

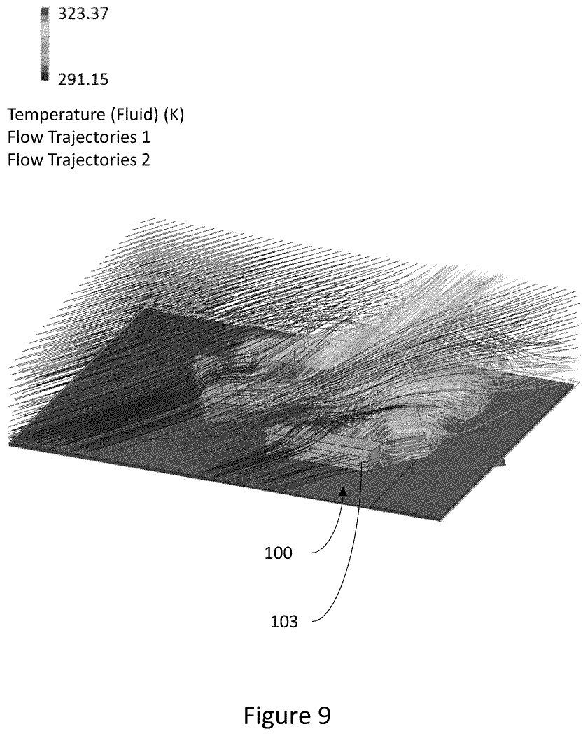

FIG. 9 schematically shows exhausted air dissipation of a data center arrangement in accordance with various embodiments. The illustrated lines represent airflow in the environment surrounding a grouping of data centers 100. The colors represent the average temperature of the air flowing at any given location. The data centers 100 are arranged such that the air intake ports 103 face outwardly and the exhaust ports 105 face inwardly. In this configuration, the wind pressure, regardless of the wind direction, is applied to the air intake ports 103 and not the exhaust ports 105 side of the data centers 100. The arrangement allows the hot exhausted air to rise (i.e. due to thermal buoyancy) before the wind can re-mix the exhausted air with cold intake air. In some embodiments, walls may also be used between structures to further optimize heat dissipation and prevent recirculation.

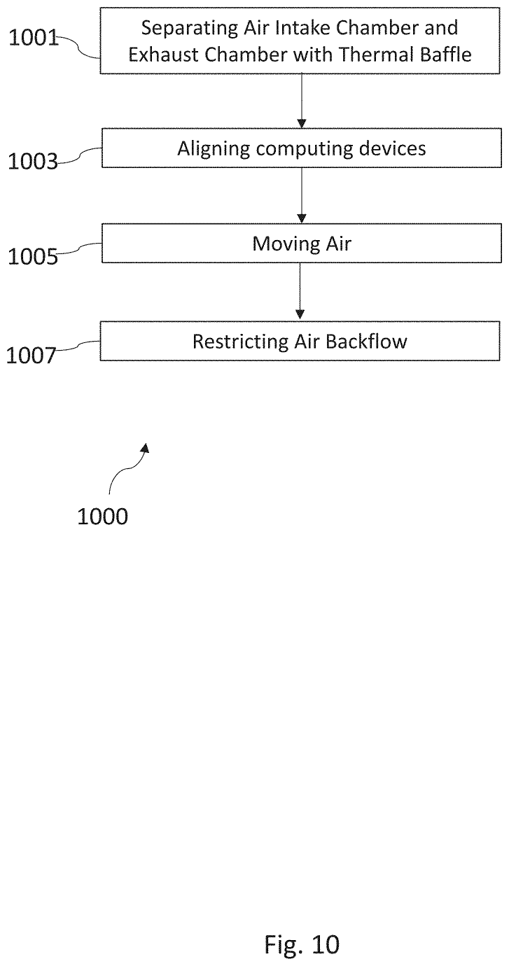

FIG. 10 shows a Process 1000 for cooling a data center in accordance with various embodiments. Process 1000 may be implemented in whole or in part in one or more of the data centers 100 disclosed herein. In certain forms the control functionalities may be performed by separate control devices. In certain forms all functionalities may be performed by the control system 16. It shall be further appreciated that a number of variations and modifications to Process 1000 are contemplated including, for example, the omission of one or more aspects of Process 1000, the addition of further conditionals and operations, or the reorganization or separation of operations and conditionals into separate processes.

Process 1000 begins with operation 1001 by separating the air intake chamber 110 and the exhaust chamber 140 by installing the thermal baffle 120. The thermal baffle may prevent hot air from backflowing into the air intake chamber after the air is warmed by the modular computing array 130. The modular computing array 130 may be positioned in the air intake chamber or the exhaust chamber 140.

After the thermal baffle 120 is installed, the computing devices 131 of the modular computing array 130 are aligned with openings 121 of the thermal baffle in operation 1003. To reduce backflow, the computing devices 131 may be installed to form an airtight seal with the openings 121.

After the thermal baffle 120 and the modular computing array 130 are installed, the data center 100 moves air through the data center 100 using air movers such as the fans of the computing devices, or the exhaust fan 150.

While air is moved through the data center 100, the coverings 123 of the thermal baffle 120 restrict air backflow from the exhaust chamber 140 to the air intake chamber 110. The coverings 123 may restrict the backflow through unused openings 121 of the thermal baffle by sealing the unused openings 121 in response to cooling fans of the modular computing array 130. For example, the cooling fans of the modular computing array 130 may move air toward the exhaust chamber 140, creating an air pressure differential between the exhaust chamber 140 and the air intake chamber 110. The pressurization of the exhaust chamber 140 pushes the coverings 123 into the unused openings 121, thus sealing the unused openings 121. To give another example, where the data center 100 has an exhaust fan, the airflow volume differential between the cooling fans of the modular computing array 130 and the exhaust fans may also cause the air pressure of the exhaust chamber 140 to increase above the air pressure of the air intake chamber 110, again sealing the unused openings 121 while air is moving through the data center 100.

In some embodiments, computing devices 131 may be removed from or moved within the data center 100, creating a new unused opening 121 of the thermal baffle 120. While air is flowing through the data center, the covering 123 corresponding to the newly unused opening 121 will also restrict air backflow from the exhaust chamber 140 to the air intake chamber 110. The cooling fan of the moved/removed computing device 131 is no longer applying a force to the covering 123, and thus air pressure of the exhaust chamber 140 can seal the opening 121 with the covering 123.

It is contemplated that the various aspects, features, processes, and operations from the various embodiments may be used in any of the other embodiments unless expressly stated to the contrary. Certain operations illustrated may be implemented by a computer executing a computer program product on a non-transient, computer-readable storage medium, where the computer program product includes instructions causing the computer to execute one or more of the operations, or to issue commands to other devices to execute one or more operations.

While the present disclosure has been illustrated and described in detail in the drawings and foregoing description, the same is to be considered as illustrative and not restrictive in character, it being understood that only certain exemplary embodiments have been shown and described, and that all changes and modifications that come within the spirit of the present disclosure are desired to be protected. It should be understood that while the use of words such as “preferable,” “preferably,” “preferred” or “more preferred” utilized in the description above indicate that the feature so described may be more desirable, it nonetheless may not be necessary, and embodiments lacking the same may be contemplated as within the scope of the present disclosure, the scope being defined by the claims that follow. In reading the claims, it is intended that when words such as “a,” “an,” “at least one,” or “at least one portion” are used there is no intention to limit the claim to only one item unless specifically stated to the contrary in the claim. The term “of” may connote an association with, or a connection to, another item, as well as a belonging to, or a connection with, the other item as informed by the context in which it is used. The terms “coupled to,” “coupled with” and the like include indirect connection and coupling, and further include but do not require a direct coupling or connection unless expressly indicated to the contrary. When the language “at least a portion” or “a portion” is used, the item can include a portion or the entire item unless specifically stated to the contrary. Unless stated explicitly to the contrary, the terms “or” and “and/or” in a list of two or more list items may connote an individual list item, or a combination of list items. Unless stated explicitly to the contrary, the transitional term “having” is open-ended terminology, bearing the same meaning as the transitional term “comprising.”

Various embodiments of the invention may be implemented at least in part in any conventional computer programming language. For example, some embodiments may be implemented in a procedural programming language (e.g., “C”), or in an object oriented programming language (e.g., “C++”). Other embodiments of the invention may be implemented as a pre-configured, stand-along hardware element and/or as preprogrammed hardware elements (e.g., application specific integrated circuits, FPGAs, and digital signal processors), or other related components.

In an alternative embodiment, the disclosed apparatus and methods (e.g., see the various flow charts described above) may be implemented as a computer program product for use with a computer system. Such implementation may include a series of computer instructions fixed either on a tangible, non-transitory medium, such as a computer readable medium (e.g., a diskette, CD-ROM, ROM, or fixed disk). The series of computer instructions can embody all or part of the functionality previously described herein with respect to the system.

Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies.

Among other ways, such a computer program product may be distributed as a removable medium with accompanying printed or electronic documentation (e.g., shrink wrapped software), preloaded with a computer system (e.g., on system ROM or fixed disk), or distributed from a server or electronic bulletin board over the network (e.g., the Internet or World Wide Web). In fact, some embodiments may be implemented in a software-as-a-service model (“SAAS”) or cloud computing model. Of course, some embodiments of the invention may be implemented as a combination of both software (e.g., a computer program product) and hardware. Still other embodiments of the invention are implemented as entirely hardware, or entirely software.

The embodiments of the invention described above are intended to be merely exemplary; numerous variations and modifications will be apparent to those skilled in the art. Such variations and modifications are intended to be within the scope of the present invention as defined by any of the appended claims. It shall nevertheless be understood that no limitation of the scope of the present disclosure is hereby created, and that the present disclosure includes and protects such alterations, modifications, and further applications of the exemplary embodiments as would occur to one skilled in the art with the benefit of the present disclosure.

What is claimed is:

1. A data center, comprising;
a housing forming an interior,
the interior including:
an air intake chamber,
a plurality of computing devices,
an exhaust chamber, and
a thermal baffle positioned between the air intake chamber and the exhaust chamber, the thermal baffle including a first plurality of openings corresponding to the plurality of computing devices and a second plurality of openings corresponding to a plurality of coverings, the plurality of coverings configured to restrict airflow from the exhaust chamber to the air intake chamber by way of the thermal baffle.

2. The data center of claim 1, comprising:
an exhaust fan configured to draw air from the exhaust chamber into an environment or an air intake fan configured to move air from the environment to the air intake chamber.

3. The data center of claim 2, wherein the plurality of computing devices includes a plurality of cooling fans.

4. The data center of claim 3, comprising a control system configured to operate at least one of the air intake fan, the exhaust fan, and the plurality of cooling fans to generate an air pressure differential between the exhaust chamber and the air intake chamber, wherein the plurality of coverings is configured to seal the second plurality of openings in response to the air pressure differential.

5. The data center of claim 1, wherein the plurality of coverings is configured to seal the second plurality of openings in response to an air pressure differential of the data center.

6. The data center of claim 1, wherein the plurality of computing devices is located in the air intake chamber, the first plurality of coverings is located on an exhaust chamber side of the thermal baffle, and a second plurality of coverings are located on the exhaust chamber side of the thermal baffle and correspond to the first plurality of openings.

7. The data center of claim 1, wherein the plurality of computing devices is at least partially located in the exhaust chamber.

8. A method for air cooling a data center, the method comprising:
separating an air intake chamber and an exhaust chamber using a thermal baffle including a plurality of openings;
aligning a plurality of computing devices with a portion of the plurality of openings;
moving air into the exhaust chamber; and
restricting, using a plurality of coverings corresponding to a remaining portion of the plurality of openings, air backflow from the exhaust chamber to the air intake chamber through the thermal baffle.

9. The method of claim 8, wherein moving air into the exhaust chamber includes operating a plurality of cooling fans of the plurality of computing devices.

10. The method of claim 9, wherein restricting the air backflow includes sealing the plurality of coverings in response to operating the plurality of cooling fans.

11. The method of claim 9, wherein moving air into the exhaust chamber includes operating an exhaust fan positioned between the exhaust chamber and an environment, and
wherein restricting the air backflow includes sealing the plurality of coverings in response to a controlled air flow volume differential between the plurality of cooling fans and the exhaust fan.

12. The method of claim 8, wherein restricting the air backflow includes pressurizing the exhaust chamber.

13. The method of claim 12, comprising:
positioning the plurality of computing devices in the air intake chamber.

14. The method of claim 8, comprising:
removing one of the plurality of computing devices from a first opening of the plurality of openings; and
restricting, using one of the plurality of coverings, air backflow from the exhaust chamber to the air intake chamber through the first opening.

15. A data center, comprising:
a plurality of computing devices;
at least one fan configured to move air through the data center; and
a thermal baffle including:
a plurality of openings configured to align with the plurality of computing devices, and
a covering configured to seal and unseal one of the plurality of openings, and configured to partially obstruct airflow through the one of the plurality of openings in one direction in response to air moving through the data center.

16. The data center of claim 15, wherein the at least one fan is at least one of a cooling fan of the plurality of computing devices, an air intake fan, or an exhaust fan.

17. The data center of claim 15, wherein the at least one fan is configured to pressurize one side of the thermal baffle.

18. The data center of claim 17, wherein the covering is configured to seal in response to pressurizing the one side of the thermal baffle.

19. The data center of claim 15, comprising an air intake chamber and an exhaust chamber, the air intake chamber and the exhaust chamber separated by the thermal baffle.

20. The data center of claim 19, comprising a housing forming an interior including the air intake chamber, the exhaust chamber, and the thermal baffle, wherein the covering partially obstructs airflow through the thermal baffle from the exhaust chamber to the air intake chamber.
